(19) United States
(12) Patent Application Publication
(10) Pub. No.: US 2006/0134858 A1
(43) Pub. Date: Jun. 22, 2006

(54) Method of manufacturing semiconductor device

(75) Inventor: Yasushi Yamazaki, Tokyo (JP)

Correspondence Address: MCDERMOTT WILL & EMERY LLP, 600 13TH STREET, N.W., WASHINGTON, DC, 20005-3096, US

(73) Assignee: Elpida Memory, Inc.

(21) Appl. No.: 11/299,672

(22) Filed: Dec. 13, 2005

(30) Foreign Application Priority Data
Dec. 17, 2004 (JP) 2004-365534

(51) Int. Cl. H01L 21/8242

(52) U.S. Cl. 438/243

(57) ABSTRACT

A silicon nitride film is formed on a P-type silicon substrate; an opening of a predetermined pattern is formed in the silicon nitride film; a gate trench is formed on the semiconductor substrate using a silicon nitride film as a mask; and then a polycrystalline silicon film is embedded inside the gate trench and within the opening to self-alignedly form a gate electrode. Further, after a high melting point metal film such as cobalt or the like is deposited on an entire surface of the silicon nitride film by a sputtering method, an annealing process is performed; and, surplus metal is further eliminated to form a silicide of these metals on the surface of the polycrystalline silicon film.

### TECHNICAL FIELD

The present invention relates to a method of manufacturing semiconductor device and, more particularly, a method of manufacturing semiconductor device having a trench gate type MOS transistor.

### BACKGROUND OF THE INVENTION

In recent years, with miniaturization of dynamic random access memory (DRAM) cell, shortening of a gate length of an access transistor of a cell array (referred to as a “cell transistor” below) cannot be avoided. However, there is a problem in that the shorter the gate length, the more remarkable the short channel effect of the transistor; consequently, the transistor threshold voltage (Vth) lowers and the subthreshold current increases. Further, in the case where concentration of impurity in the substrate is increased so as to suppress the lowering of the Vth, there is a problem in that degradation of refresh characteristics in DRAM becomes serious because junction leakage increases.

In order to avoid this problem, what we call a trench gate type transistor (also known as recess channel transistor), in which a gate electrode is embedded in a trench formed on a silicon substrate, is brought to attention (refer to Japanese Patent Application Laid-Open Nos. 9-232535, 2002-261256, and 2003-78033). According to a trench gate type transistor, an effective channel length (gate length) can be physically and sufficiently secured and it is possible to realize a minute DRAM having an F-number of 90 nm or below.

A method of manufacturing DRAM having a known trench gate type cell transistor is as follows. First, as shown in FIG. 16, after an element isolation region 202 such as shallow trench isolation (STI) is formed on a P-type silicon substrate 201, a protective insulating film 203 is formed on the P-type silicon substrate 201. Then, this is subjected to patterning; and after that, the P-type silicon substrate 201 is subjected to dry etching using the protective insulating film 203 as a mask, thereby forming a trench (gate trench) 204 at a predetermined region in which a gate electrode is to be formed as shown in FIG. 17.

Next, as shown in FIG. 18, the protective insulating film 203 is removed; and a silicon oxide film is formed on an entire surface of the silicon substrate 201 including an inside of the gate trench 204 by performing thermal oxidation on the P-type silicon substrate 201. This leads to a state that a gate insulating film 205 is formed in an inner wall of the gate trench 204. After that, as shown in FIG. 19, a polycrystalline silicon (Poly-Si) film 206 and a silicide film 207 are formed sequentially; and the polycrystalline silicon film 206 and the silicide film 207 other than a part to be the gate electrode are subjected to patterning using a photo resist as a mask, thereby completing a trench gate electrode 209 as shown in FIG. 20. After that, as shown in FIG. 21, phosphorus (P) is introduced by means of ion implantation on both sides of the gate electrode 209 to form an N type diffusion layer 210 which is to be source/drain regions of the transistor; thereby completing a trench gate type cell transistor. Further, although not shown in the drawing, various kinds of wiring and a cell capacitor are laminated using a general method to complete DRAM.

However, there is the following problem in the above-mentioned known manufacturing method. As shown in FIG. 22, in the case where a position deviation of a mask pattern 211 occurs due to the photo resist with respect to the gate trench 204, a slit region 212 and an offset region 213 are formed as shown in FIG. 23. The slit region 212 is a gap between a side wall of the gate electrode 209 and the inner wall of the gate trench 204, and the offset region 213 is a clearance between the N type diffusion layer 210 and the gate trench 204. The slit region 212 causes to increase junction leakage, and the offset region 213 gives negative effect on electrical characteristics between the source and drain; therefore, there is a problem in that the characteristics of the cell transistor degrade where those are formed.

### SUMMARY OF THE INVENTION

The present invention has been made to solve the problem described above. It is therefore an object of the present invention to provide a method of manufacturing semiconductor device having a trench gate type transistor with good characteristics.

The above and other objects of the present invention can be accomplished by a method of manufacturing semiconductor device, comprising: a first step for forming a protective insulating film on a semiconductor substrate; a second step for forming an opening of a predetermined pattern in said protective insulating film; a third step for forming a gate trench on said semiconductor substrate using said protective insulating film as a mask; a fourth step for forming a gate electrode by embedding electrode material inside said gate trench and within said opening; and a fifth step for eliminating said protective insulating film.

According to the present invention, since a gate electrode is self-alignedly formed with respect to a gate trench with a protective insulating film used as a mask in forming the gate electrode, the protective insulating film being used as a mask in forming the gate trench, a deviation does not occur at the position of the gate electrode; therefore, a slit region and/or an offset region cannot be formed. Consequently, a semiconductor device having a trench gate type transistor with good characteristics can be manufactured.

In a preferred embodiment of the present invention, the fourth step includes: an electrode material film deposition step for depositing said electrode material on said protective insulating film and inside said gate trench; and a step for eliminating unnecessary part of said electrodematerial on saidprotective insulating film. In this case, the electrode material film deposition step preferably includes: a step for completely embedding the inside of said gate trench with a polycrystalline silicon film; and a step of performing silicidation of the surface of said polycrystalline silicon film by thermal anneal after forming a high melting point metal film on the entire surface of said semiconductor substrate. According to this, resistance of the trench gate electrode can be reduced.

In a further preferred embodiment of the present invention, the electrode material film deposition step includes: a step for forming a concave part inside said gate trench with said polycrystalline silicon film; and a step for forming a silicide film in said concave part with said polycrystalline silicon film. According to this, resistance of the trench gate electrode can be further reduced.

In a further preferred embodiment of the present invention, the electrode material film deposition step includes: a step for forming a concave part inside said gate trench with said polycrystalline silicon film; and a step for forming a high melting point metal film in said concave part with said polycrystalline silicon film. According to this also, resistance of the trench gate electrode can be further reduced.

It is preferably that the protective insulating film is a silicon nitride film. According to this, CMP can be used in eliminating gate electrode material formed on a protective insulating film and the protective insulating film can be used as a stopper in polishing by CMP.

It is preferably that the present invention further comprises a sixth step for oxidizing said gate electrode. According to this, dielectric strength voltage of the trench gate electrode can be sufficiently secured.

According to the present invention, since a gate electrode is self-alignedly formed with respect to the gate trench with the protective insulating film used as a mask pattern in forming the gate electrode, the protective insulating film being used as a mask pattern in forming the gate trench, a deviation does not occur at the position of the gate electrode; therefore, a slit region and/or an offset region cannot be formed. Consequently, a semiconductor device having a trench gate type transistor with good characteristics can be manufactured.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic sectional view showing a process (a step of forming an element isolation region and a protective insulating film) of a method of manufacturing DRAM according to a first embodiment of the present invention;

FIG. 2 is a schematic sectional view showing a process (a step of forming an opening) of a method of manufacturing DRAM according to the first embodiment of the present invention;

FIG. 3 is a schematic sectional view showing a process (a step of forming a gate trench) of a method of manufacturing DRAM according to the first embodiment of the present invention;

FIG. 4 is a schematic sectional view showing a process (a step of forming a gate oxide film) of a method of manufacturing DRAM according to the first embodiment of the present invention;

FIG. 5 is a schematic sectional view showing a process (a step of forming a polycrystalline silicon film) of a method of manufacturing DRAM according to the first embodiment of the present invention;

FIG. 6 is a schematic sectional view showing a process (a step of eliminating a polycrystalline silicon film by CMP method) of a method of manufacturing DRAM according to the first embodiment of the present invention;

FIG. 7 is a schematic sectional view showing a process (a step of forming a high melting point metal film) of a method of manufacturing DRAM according to the first embodiment of the present invention;

FIG. 8 is a schematic sectional view showing a process (a step of forming a silicide layer) of a method of manufacturing DRAM according to the first embodiment of the present invention;

FIG. 9 is a schematic sectional view showing a process (a step of eliminating silicon nitride film and performing thermal oxidation) of a method of manufacturing DRAM according to the first embodiment of the present invention;

FIG. 10 is a schematic sectional view showing a process (a step of forming an N type diffusion layer) of a method of manufacturing DRAM according to the first embodiment of the present invention;

FIG. 11 is a schematic sectional view showing a process (a step of forming a wiring and cell capacitor) of a method of manufacturing DRAM according to the first embodiment of the present invention;

FIG. 12 is a schematic sectional view showing a process (a step of forming a poly crystalline silicon film and silicide layer) of a method of manufacturing DRAM according to a second embodiment of the present invention;

FIG. 13 is a schematic sectional view showing a process (a step of eliminating a polycrystalline silicon film and a silicide layer by CMP method) of a method of manufacturing DRAM according to the second embodiment of the present invention;

FIG. 14 is a schematic sectional view showing a process (a step of eliminating silicon nitride film and performing thermal oxidation) of a method of manufacturing DRAM according to the second embodiment of the present invention;

FIG. 15 is a schematic sectional view showing a process (a step of forming a poly crystalline silicon film, tungsten nitride film and a tungsten film) of a method of manufacturing DRAM according to a third embodiment of the present invention;

FIG. 16 is a schematic sectional view showing a process (a step of forming an element isolation region and a protective insulating film) of a method of manufacturing DRAM according to the prior art;

FIG. 17 is a schematic sectional view showing a process (a step of forming an opening and gate trench) of a method of manufacturing DRAM according to the prior art;

FIG. 18 is a schematic sectional view showing a process (a step of eliminating a protective insulating film and forming a gate oxide film) of a method of manufacturing DRAM according to the prior art;

FIG. 19 is a schematic sectional view showing a process (a step of forming a poly crystalline silicon film and silicide layer) of a method of manufacturing DRAM according to the prior art;

FIG. 20 is a schematic sectional view showing a process (a step of patterning a poly crystalline silicon film and silicide layer) of a method of manufacturing DRAM according to the prior art;

FIG. 21 is a schematic sectional view showing a process (a step of forming an N type diffusion layer) of a method of manufacturing DRAM according to the prior art;

FIG. 22 is a schematic sectional view for showing a problem of a known method of manufacturing DRAM; and

FIG. 23 is a schematic sectional view for showing a problem of a known structure of a trench gate electrode.

### DETAILED DESCRIPTION OF THE EMBODIMENTS

Preferred embodiments in the case where a subject of the present invention is a cell transistor of DRAM will be described below with reference to the accompanying drawings.

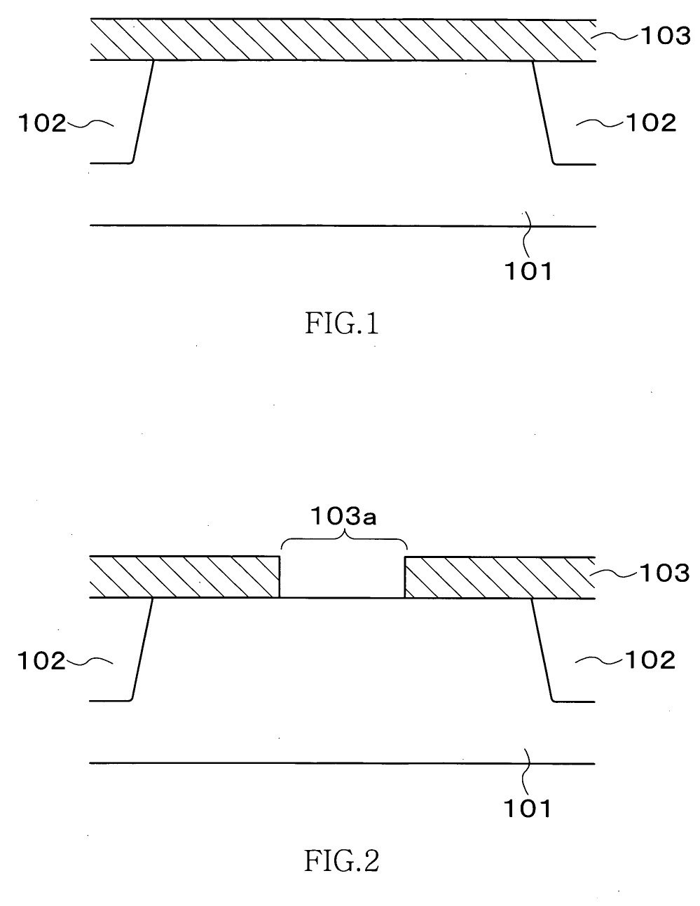

FIG. 1 to FIG. 11 are schematic sectional views showing manufacturing processes of DRAM according to a first embodiment of the present invention.

First, as shown in FIG. 1, in the manufacturing of DRAM, element isolation regions 102 having a depth of approximately 250 to 350 nm are formed on the surface of a P-type silicon substrate 101 by a STI method. After that, a silicon nitride film 103 having approximately 100 to 200 nm is deposited on the surface of the P-type silicon substrate 101 by a CVD method.

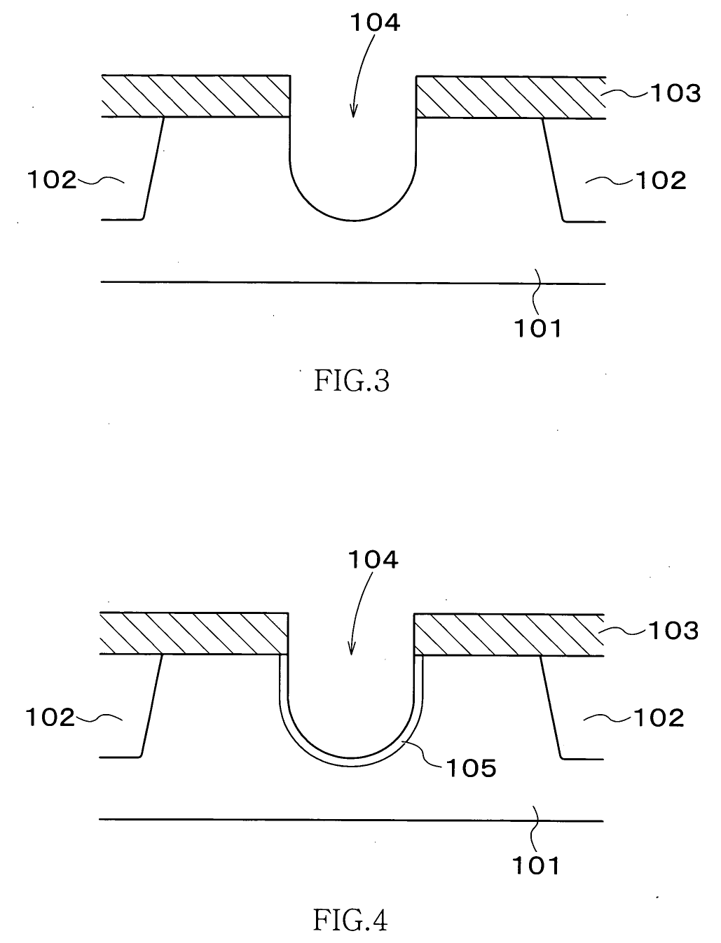

Next, as shown in FIG. 2, the silicon nitride film 103 is selectively eliminated by a photolithography technology, thereby forming an opening 103a of a predetermined pattern in the silicon nitride film 103. Then, the P-type silicon substrate 101 is subjected to dry etching using this silicon nitride film 103 as a mask, thereby forming a trench (gate trench) 104 having a depth of approximately 100 to 200 nm in a predetermined region to be formed by a channel region (a gate electrode), as shown in FIG. 3. In addition, it is preferable if a section shape of the gate trench 104 has a uniform and substantially U-shaped curvature in order to uniform film quality of a gate oxide film to be described later.

Next, boron (B) of approximately 10¹³ to 10¹⁴/cm² is introduced by means of ion implantation inside the gate trench 104 and the threshold voltage (Vth) of the transistor is adjusted (channel doping); and then, a gate oxide film 105 of approximately 6 to 8 nm is formed in the inner wall of the gate trench 104 by thermal oxidation, as shown in FIG. 4. In addition, it is preferable to perform ion implantation through the silicon oxide film which is formed inside the gate trench 104 when channel doping is performed. In this case, the gate oxide film 105 is formed after eliminating the silicon oxide film.

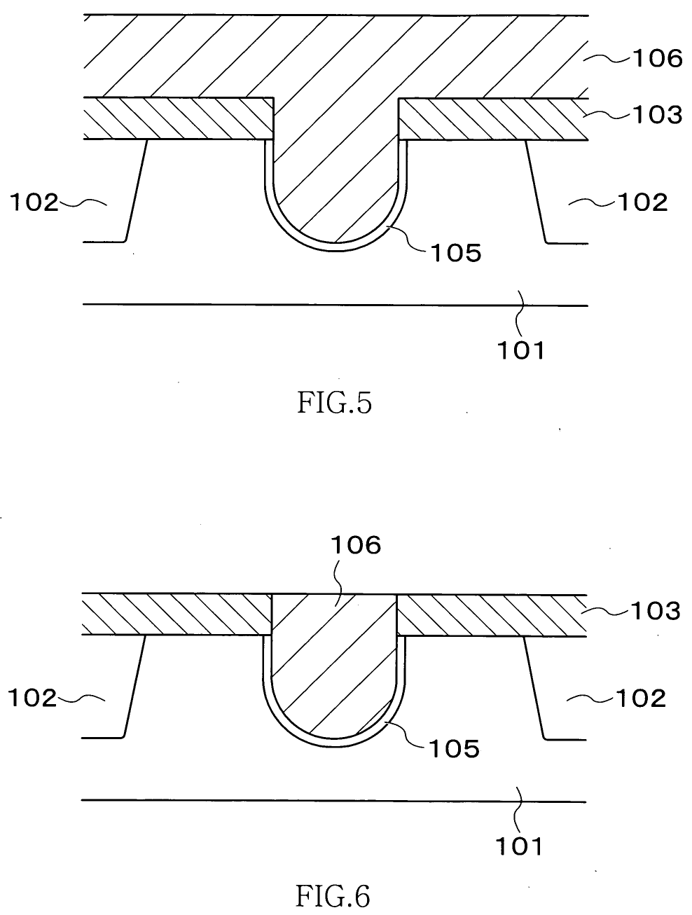

Next, as shown in FIG. 5, a polycrystalline silicon film (phosphorus doped polycrystalline silicon film) 106, which is doped with N-type impurities such as phosphorus (P) by a CVD method, is deposited on an entire surface of the P-type silicon substrate 101 including the inside of the gate trench 104. Then, as shown in FIG. 6, the polycrystalline silicon film 106 is polished by a chemical mechanical polishing (CMP) method until an upper surface of the silicon nitride film 103 is exposed in order to leave the polycrystalline silicon film 106 inside the gate trench 104 and within the opening 103a of the silicon nitride film 103. At this time, since the silicon nitride film 103 becomes a stopper with respect to the CMP, only unnecessary part of the polycrystalline silicon film 106 can be surely eliminated and sufficient flatness of the surface can be secured.

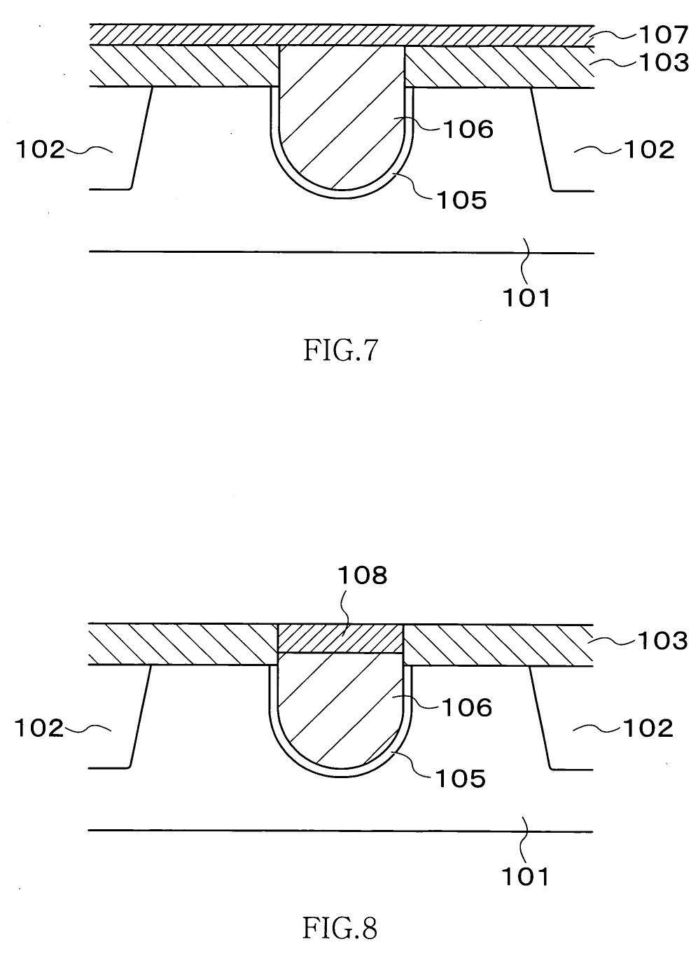

Next, a silicide layer 108 is selectively formed on the surface of the polycrystalline silicon film 106. At this time, the silicon nitride film 103 used for forming the gate trench 104 can be used as a mask. That is, as shown in FIG. 7, a high melting point metal film 107 such as cobalt (Co), titanium (Ti), or nickel (Ni) is deposited on the entire surface of the substrate by a sputtering method. After that, an annealing process is performed to form the silicide layer 108 by reacting the high melting point metal film 107 with the surface of the polycrystalline silicon film 106. Furthermore, as shown in FIG. 8, unnecessary high melting point metal film 107 which has not reacted with the polycrystalline silicon film 106 is eliminated by wet etching using sulfuric acid, hydrochloric acid, or the like. Thus, a gate electrode 109 composed of the polycrystalline silicon film 106, and the silicide layer 108 is completed.

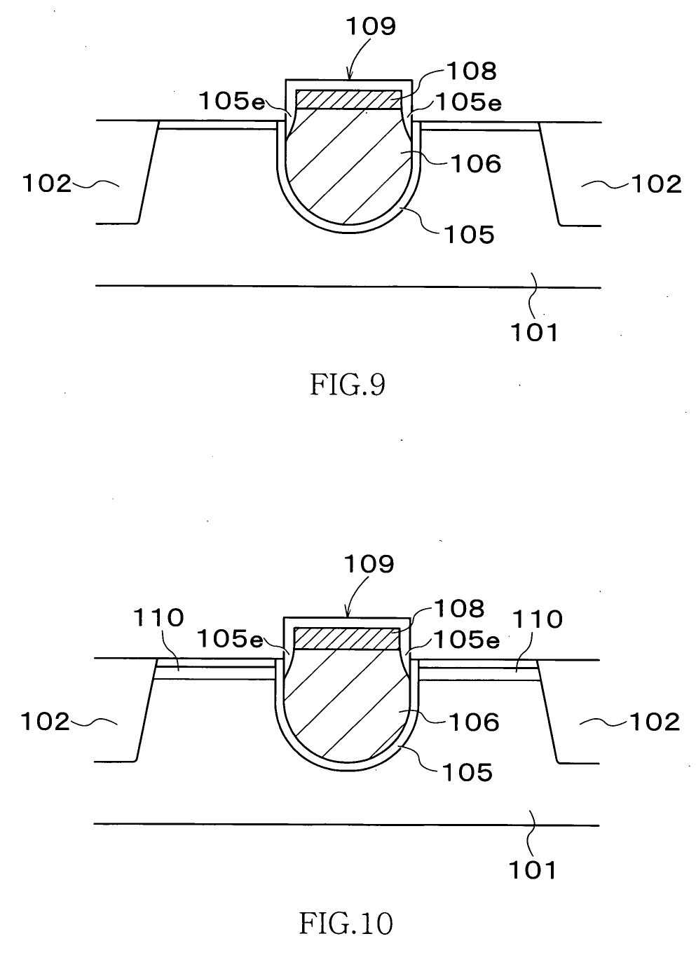

Then, as shown in FIG. 9, after the silicon nitride film 103 is eliminated using hot phosphoric acid (H₃PO₄), the gate insulating film 105 is reinforced by performing thermal oxidation. By this, the surface of the P-type silicon substrate 101, the exposed surface of the polycrystalline silicon film 106, and the surface of the silicide 109 are oxidized to newly form a gate insulating film 105e in the vicinity of the edge of the gate insulating film 105; therefore, dielectric strength voltage of the gate insulating film 105 can be enhanced. After this, as shown in FIG. 10, phosphorus (P) of approximately 10¹⁴ to 10¹⁵/cm² is introduced by means of ion implantation in both side regions of the gate electrode 109 on the silicon substrate 101 to form an N type diffusion layer 110 which becomes source/drain regions of the transistor. A trench gate type transistor of the present embodiment is completed by the above process.

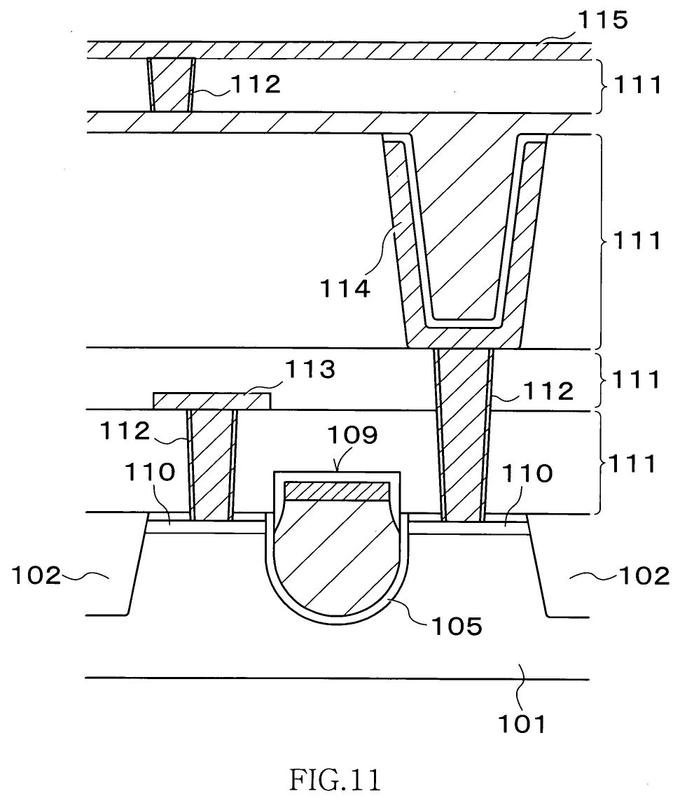

After that, in the manufacturing of DRAM, various kinds of wiring and a cell capacitor are formed using a well known method. That is, as shown in FIG. 11, an interlayer dielectric film 111 is formed on the cell transistor and also a contact plug 112 passing through the interlayer dielectric film 111, a bit line 113, a cell capacitor 114, Al wiring 115, and the like are formed, thereby completing DRAM with a trench gate type cell transistor.

As described above, according to the present embodiment, since the gate electrode is self-alignedly formed with respect to the gate trench with the protective insulating filmused as a mask in forming the gate electrode, the protective insulating film being used as a mask in forming the gate trench, a deviation does not occur at the position of the gate electrode; therefore, a slit region and/or an offset region are/is not formed and a trench gate type transistor with good characteristics can be manufactured. Consequently, DRAM with high quality and a large capacity can be manufactured by using this as a cell transistor of DRAM.

In the above-mentioned first embodiment, the case where a silicide layer is formed on the surface of a polycrystalline silicon film completely embedded inside a gate trench is described; however, the following may be performed for further reducing resistance of a gate electrode.

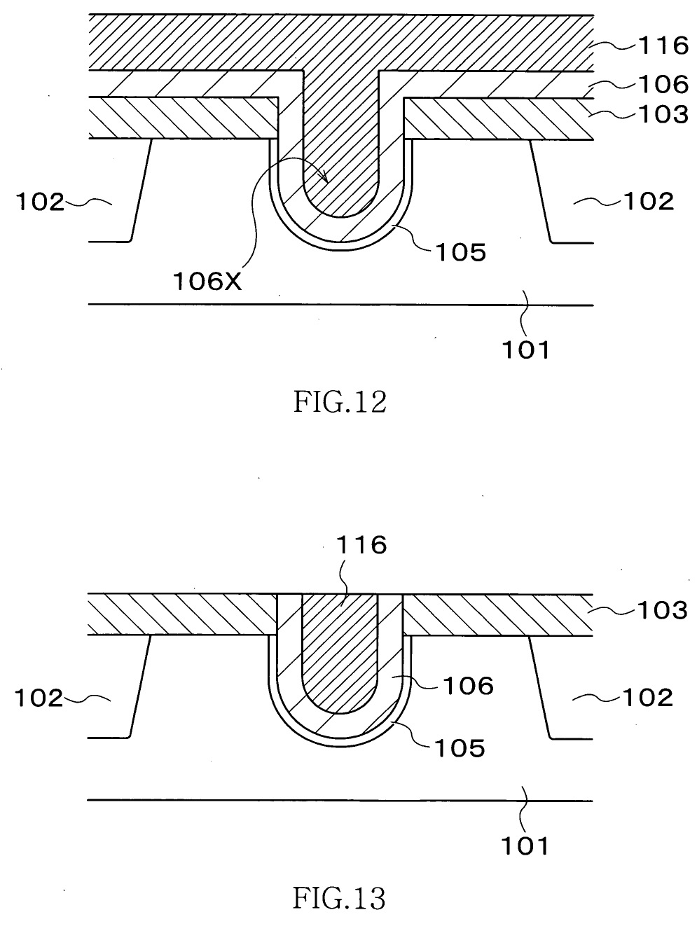

FIG. 12 to FIG. 14 are schematic sectional views for schematically showing a part of manufacturing process of DRAM according to a second embodiment of the present invention.

In the present embodiment, a sequence of process until a gate oxide film 105 is formed by forming a gate trench 104 on a P-type silicon substrate 101, is the same as the process of the first embodiment shown in FIG. 1 to FIG. 4; however, as shown in FIG. 12, a different point from the first embodiment is that a polycrystalline silicon film 106 is comparatively thinly formed so that a concave part 106X with the polycrystalline silicon film 106 is formed inside the gate trench 104. By thinly forming the polycrystalline silicon film 106, the inside of the gate trench 104 is not completely embedded with the polycrystalline silicon film 106; consequently, it becomes a state where the concave part 106X with the polycrystalline silicon film 106 is formed. Then, in this state, a silicide film 116 is deposited on the entire surface of the substrate by a sputtering method or CVD method.

Then, the silicide film 116 and the polycrystalline silicon film 106 are polished by a CMP method until an upper surface of a silicon nitride film 103 is exposed so that these remain inside the gate trench 104 and within the opening of the silicon nitride film 103, as shown in FIG. 13. At this time, since the silicon nitride film 103 becomes a stopper with respect to the CMP, only unnecessary part of the silicide film 116 and the polycrystalline silicon film 106 can be surely eliminated and sufficient flatness of the surface can be secured.

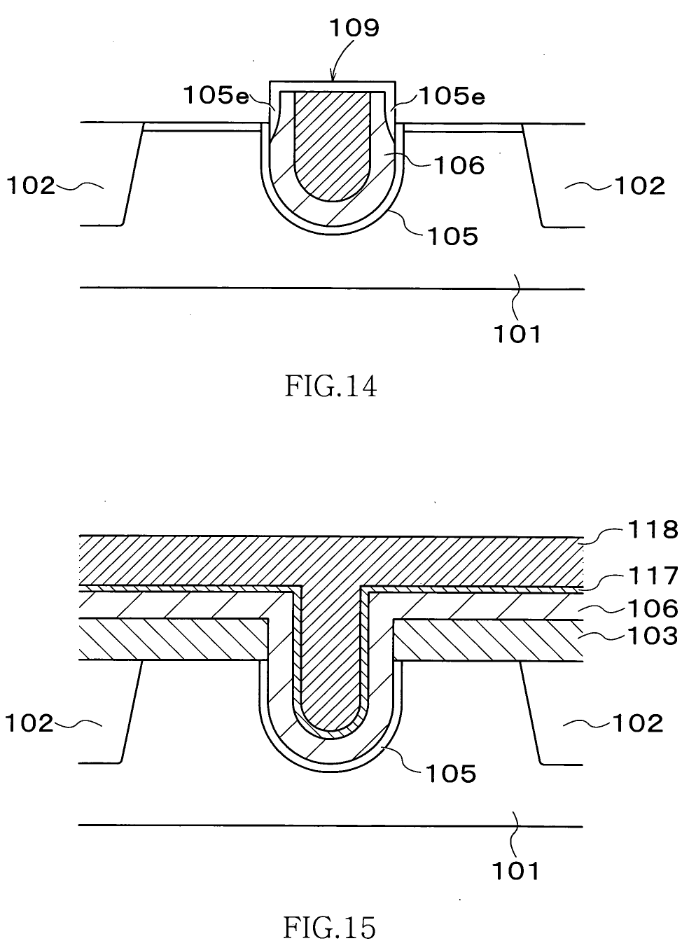

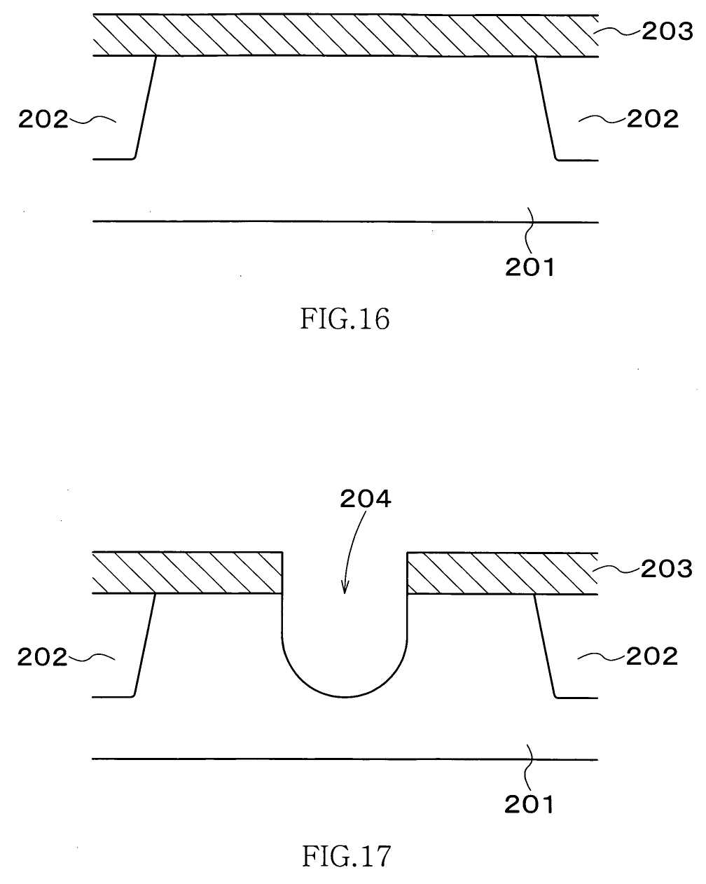

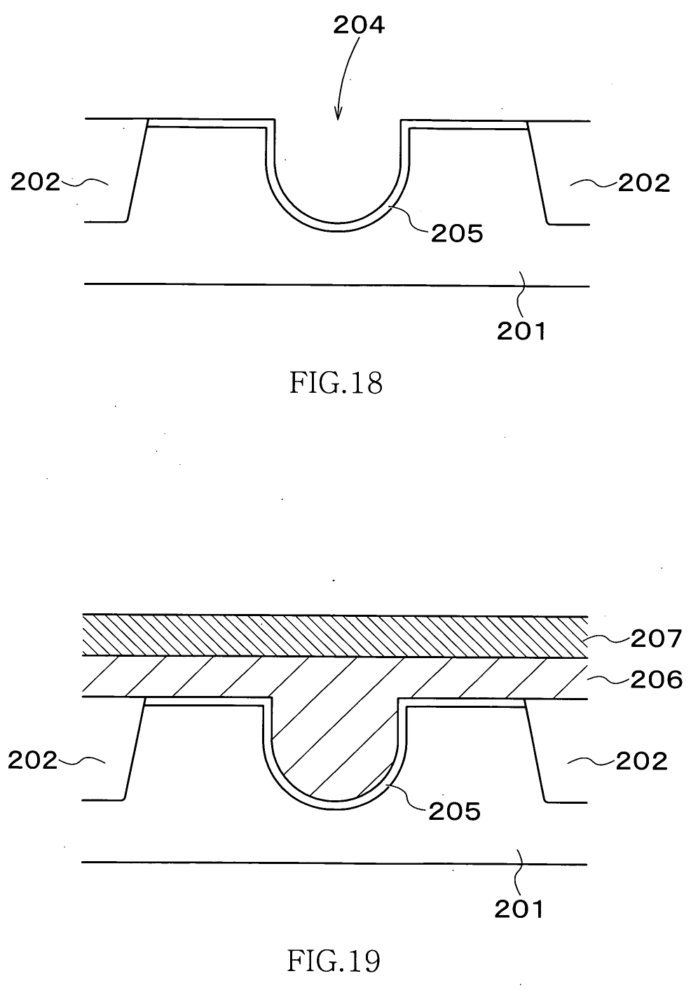

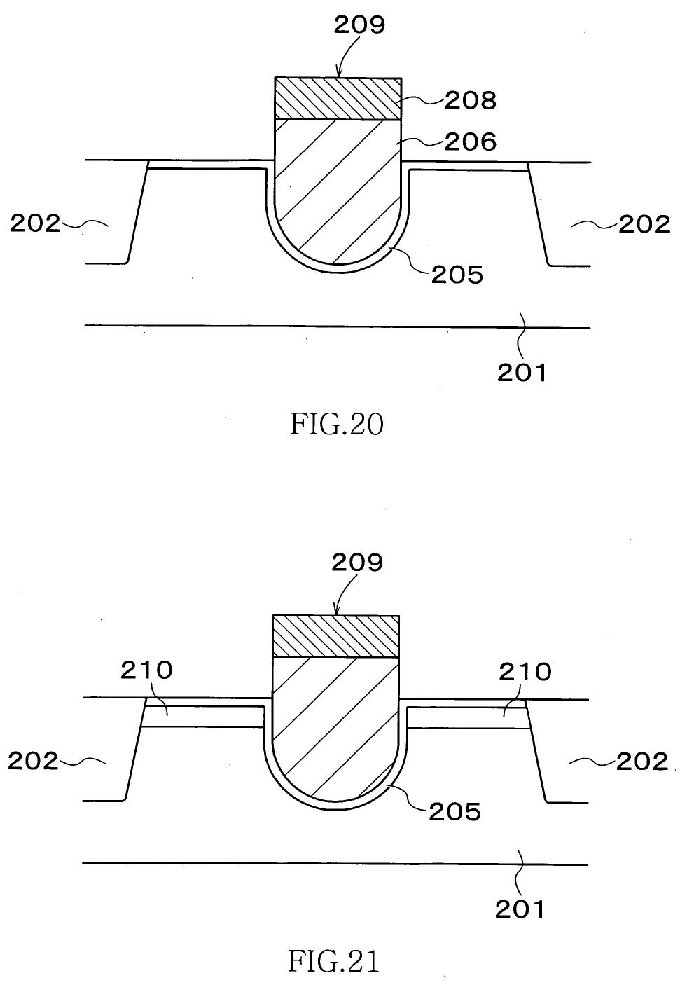

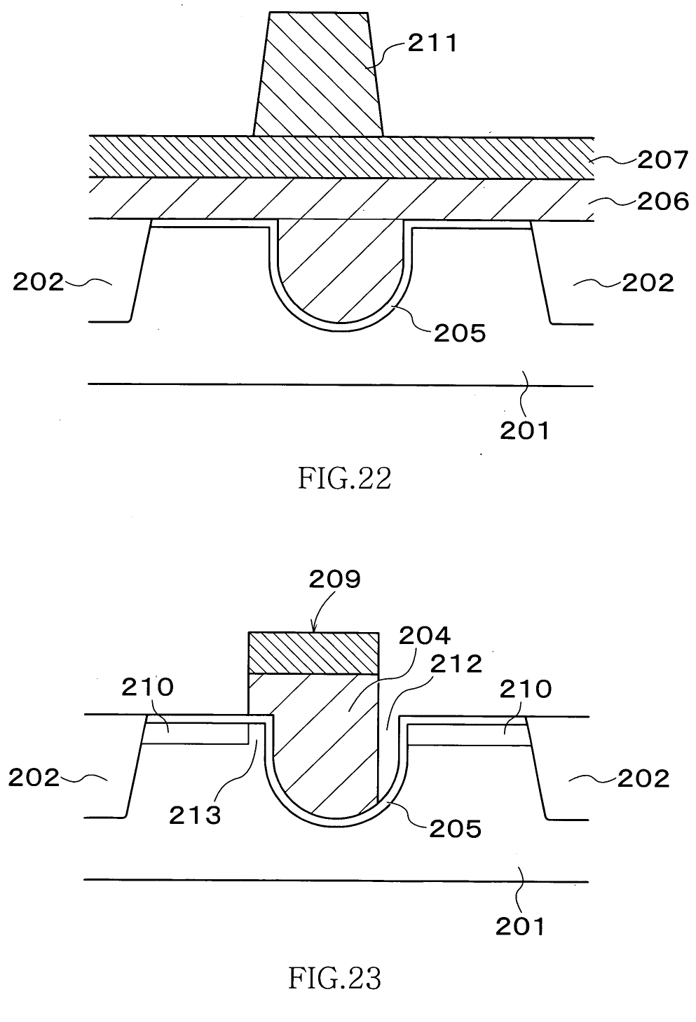

Then, as shown in FIG. 14, after the silicon nitride film 103 is eliminated using hot phosphoric acid (H₃PO₄), the gate oxide film 105 is reinforced by thermal oxidation. By this, the surface of the P-type silicon substrate 101, the exposed surface of the polycrystalline silicon film 106, and the surface of a silicide 109 are oxidized to newly form a gate insulating film 105e in the vicinity of the edge of the gate insulating film 105; therefore, dielectric strength voltage of the gate insulating film 105 can be enhanced. After this, phosphorus (P) of approximately 10¹⁴ to 10¹⁵/cm² is introduced by means of ion implantation in both side regions of a gate electrode 109 on the silicon substrate 101 to form an N type diffusion layer 110 which becomes source/drain regions of the transistor. A trench gate type transistor of the present embodiment is completed by the above process. Since the subsequent process is the same as that of the first embodiment, redundant description will not be repeated.

As described above, according to the present embodiment, since a silicide film is formed to the inside of a gate trench, resistance of a trench gate electrode can be reduced in addition to the effects of the first embodiment.

In the above-mentioned second embodiment, the case where a silicide film is formed in the concave part of a polycrystalline silicon film formed inside a gate trench is described; however, the following may be performed for further reducing resistance of the gate electrode.

FIG. 15 is a schematic sectional view for schematically showing a part of manufacturing process of DRAM according to a third embodiment of the present invention.

As shown in FIG. 15, in the present embodiment, a tungsten nitride film (WN) 117 and a tungsten film (W) 118 are sequentially deposited to form a polymetal gate electrode in a gate trench 104, in place of the silicide film 116 shown in FIG. 12 in the second embodiment. After that, the tungsten film 118, nitride tungsten film 117, and a polycrystalline silicon film 106 are polished by a CMP method until an upper surface of a silicon nitride film 103 is exposed so that these remain inside the gate trench 104 and within the opening of the silicon nitride film 103.

After that, a trench gate type transistor of the present embodiment is completed by eliminating the silicon nitride film 103, reinforcing a gate oxide film 105 by selective oxidation under Wet-Hydrogen atmosphere, and forming an N type diffusion layer 110 which becomes source/drain regions of the transistor. Since the subsequent process is the same as those of the first and the second embodiments, redundant description will not be repeated.

As described above, according to the present embodiment, since a tungsten film is formed to the inside of a gate trench, resistance of a trench gate electrode can be further reduced in addition to the effects of the first and the second embodiments.

The present invention is in no way limited to the aforementioned embodiments, but rather various modifications are possible within the scope of the invention as recited in the claims, and naturally these modifications are included within the scope of the invention.

For example, DRAM is shown as an example of the semiconductor device in each of the above-mentioned embodiments; however, the present invention is not limited to this, but it is applicable to the manufacturing of any semiconductor device having a trench gate type transistor. In this regard, however, the present invention has a remarkable effect in DRAM in that the transistor cell array can be miniaturized.

Further, in each of the above-mentioned embodiments, a silicon nitride film is directly formed on the surface of the P-type silicon substrate as the protective insulating film; however, a silicon oxide film of approximately 10 to 20 nm is formed on the surface of the P-type silicon substrate as a buffer layer, and the silicon nitride film may be formed via this silicon oxide film. Furthermore, the silicon nitride film is used as the protective insulating film, but other material such as the silicon oxide film or the like can be used.

Further, in each of the above-mentioned embodiments, an element isolation region is formed by a STI method, but the method is not limited to this and it is needless to say that a LOCOS method or the like may be used.

Further, in each of the above-mentioned embodiments, when the polycrystalline silicon film 106 remains inside the gate trench 104, the polycrystalline silicon film 106 is polished by a CMP method; however, the polycrystalline silicon film 106 can also be eliminated by etch back.

Further, in each of the above-mentioned embodiments, the gate electrode 109 has a laminated structure composed of the polycrystalline silicon film 106, silicide layer 108, and the like; however, the gate electrode 109 may be a single layer structure made up of only the polycrystalline silicon film 106, for example.

Further, in the above-mentioned embodiments, the case where the N channel MOS transistor using the P-type silicon substrate is applied is described as an example; however, the present invention is not limited to this; it can also be applicable to a P channel MOS transistor. Furthermore, if necessary, a P well and/or an N well may be formed.

What is claimed is:

1. A method of manufacturing semiconductor device, comprising:
a first step for forming a protective insulating film on a semiconductor substrate;
a second step for forming an opening of a predetermined pattern in said protective insulating film;
a third step for forming a gate trench on said semiconductor substrate using said protective insulating film as a mask;
a fourth step for forming a gate electrode by embedding electrode material inside said gate trench and within said opening; and
a fifth step for eliminating said protective insulating film.

2. The method of manufacturing semiconductor device as claimed in claim 1, wherein said fourth step includes:
an electrode material film deposition step for depositing said electrode material on said protective insulating film and inside said gate trench; and
a step for eliminating unnecessary part of said electrode material on said protective insulating film.

3. The method of manufacturing semiconductor device as claimed in claim 2, wherein said electrode material film deposition step includes:
a step for completely embedding the inside of said gate trench with a polycrystalline silicon film; and
a step of performing silicidation of the surface of said polycrystalline silicon film by thermal anneal after forming a high melting point metal film on the entire surface of said semiconductor substrate.

4. The method of manufacturing semiconductor device as claimed in claim 2, wherein said electrode material film deposition step includes:
a step for forming a concave part inside said gate trench with said polycrystalline silicon film; and
a step for forming a silicide film in said concave part with said polycrystalline silicon film.

5. The method of manufacturing semiconductor device as claimed in claim 2, wherein said electrode material film deposition step includes:
a step for forming a concave part inside said gate trench with said polycrystalline silicon film; and
a step for forming a high melting point metal film in said concave part with said polycrystalline silicon film.

6. The method of manufacturing semiconductor device as claimed in claim 1, wherein said protective insulating film is a silicon nitride film.

7. The method of manufacturing semiconductor device as claimed in claim 1, further comprising a sixth step for oxidizing said gate electrode.
